(19) United States
(12) Patent Application Publication
(10) Pub. No.: US 2025/0380595 A1
(43) Pub. Date: Dec. 11, 2025

(54) DISPLAY DEVICE, METHOD OF FABRICATING DISPLAY DEVICE, AND ELECTRONIC DEVICE

(71) Applicant: SAMSUNG DISPLAY CO., LTD., YONGIN-SI (KR)

(72) Inventors: Woo Yong SUNG, Yongin-si (KR); Kwan Hyuck YOON, Yongin-si (KR); Sang Yeon HWANG, Yongin-si (KR); Seung Yong SONG, Yongin-si (KR)

(21) Appl. No.: 19/175,316

(22) Filed: Apr. 10, 2025

(30) Foreign Application Priority Data
Jun. 11, 2024 (KR) 10-2024-0075801

(51) Int. Cl. H10K 59/80; H10K 59/122; H10K 59/40; H10K 102/10

(52) U.S. Cl. CPC H10K 59/87; H10K 59/122; H10K 59/40; H10K 2102/101

(57) ABSTRACT

A display device may include a substrate, a pixel circuit layer disposed on the substrate, a light-emitting-element layer disposed on the pixel circuit layer, and including light emitting elements, a first inorganic insulating layer disposed on the light-emitting-element layer, a first organic insulating layer disposed on the first inorganic insulating layer, and defining trenches in an area between the light emitting elements, a second inorganic insulating layer disposed on the first organic insulating layer, a second organic insulating layer disposed on the second inorganic insulating layer and capping the trenches, a plurality of touch electrodes disposed on the second organic insulating layer, and a plurality of air cavities defined by the trenches and the second organic insulating layer.

### CROSS-REFERENCE TO RELATED APPLICATION

This application claims priority under 35 U.S.C. § 119(a) to Korean Patent Application number 10-2024-0075801, filed on Jun. 11, 2024, in the Korean Intellectual Property Office, the disclosure of which is incorporated by reference herein in its entirety.

### BACKGROUND

### Technical Field

Various embodiments of the present disclosure relate to a display device, a method of fabricating a display device, and an electronic device.

### Discussion of Related Art

Electronic devices provided with touch panels have the capability to indicate positions through touch. With the proliferation of mobile electronic devices such as smartphones and tablet computers, touch panels have become widely used. As touch panels become more widely used, there is a growing need for technologies that can enhance the accuracy of touch detection and improve the response time for touch inputs.

The accuracy of touch detection may be enhanced as the influence of noise from signals generated by touch is reduced. The noise may increase as the capacitance between a touch electrode and a cathode electrode increases.

### SUMMARY

Various embodiments of the present disclosure are directed to a display device having improved efficiency, a method of fabricating the display device, and an electronic device. For example, the display device may include an organic insulating layer with air cavities that may reduce permittivity, thereby enhancing touch efficiency.

An embodiment of the present disclosure may provide a display device, including: a substrate; a pixel circuit layer disposed on the substrate; a light-emitting-element layer disposed on the pixel circuit layer, and including light emitting elements; a first inorganic insulating layer disposed on the light-emitting-element layer; a first organic insulating layer disposed on the first inorganic insulating layer, and defining trenches in an area between the light emitting elements; a second inorganic insulating layer disposed on the first organic insulating layer; a second organic insulating layer disposed on the second inorganic insulating layer and capping the trenches; a plurality of touch electrodes disposed on the second organic insulating layer; and a plurality of air cavities defined by the trenches and the second organic insulating layer.

The second inorganic insulating layer may contact inner surfaces of the trenches.

The display device may further include a hydrophobic layer disposed in the trenches and between the second inorganic insulating layer and the air cavities.

The hydrophobic layer may contact the second inorganic insulating layer in the trenches.

In an embodiment, a contact angle of the hydrophobic layers with respect to the second organic insulating layer may be 90 degrees or more.

In an embodiment, a sensing panel may be disposed on the second organic insulating layer.

The substrate may include a display area and a non-display area formed around the display area. The plurality of air cavities may include first air cavities disposed adjacent to a center portion of the display area, and second air cavities disposed adjacent to the non-display area. A number of first air cavities per unit surface area may be equal to or greater than a number of second air cavities per unit surface area.

In an embodiment, any one of the second air cavities may have a shape different from a shape of any one of the first air cavities.

The light-emitting-element layer may further include: anode electrodes disposed on the pixel circuit layer; a sacrificial layer disposed on the anode electrodes along a peripheral portion of each of the anode electrodes; and a pixel defining layer disposed on the pixel circuit layer, portions of the anode electrodes, and the sacrificial layer.

The trenches may overlap the pixel defining layer.

The display device may further include a sidewall structure disposed between the light-emitting-element layer and the first inorganic insulating layer, and overlapping the pixel defining layer.

The sidewall structure may include a first metal layer adjacent to the pixel defining layer, and a second metal layer disposed on the first metal layer. The second metal layer may have a width greater than a width of the first metal layer.

The light-emitting-element layer may further include: emission layers disposed on the anode electrodes; and cathode electrodes disposed on the emission layers. The emission layers and the cathode electrodes may contact side surfaces of the sidewall structure.

The first inorganic insulating layer may contact the sidewall structure and the cathode electrodes.

The first organic insulating layer may have a permittivity of about 2.5 or less.

An embodiment of the present disclosure may provide a method of fabricating a display device, including: forming a pixel circuit layer on a substrate; forming a light-emitting-element layer including light emitting elements on the pixel circuit layer; forming a first inorganic insulating layer on the light-emitting-element layer; forming, on the first inorganic insulating layer, a first organic insulating layer defining trenches in an area between the light emitting elements; forming a second inorganic insulating layer on the first organic insulating layer; and forming a second organic insulating layer on the second inorganic insulating layer; and providing a plurality of touch electrodes on the second organic insulating layer. Air cavities may be disposed in the trenches between the second inorganic insulating layer and the second organic insulating layer.

A method may further include forming, in the trenches, hydrophobic layers contacting the second inorganic insulating layer.

A method may further include providing a sensing panel including the plurality of touch electrodes on the second organic insulating layer.

An embodiment of the present disclosure may provide an electronic device including: a display panel; and a sensing panel disposed on the display panel, and including touch electrodes. The display panel may include: a substrate; a pixel circuit layer disposed on the substrate; a light-emitting-element layer disposed on the pixel circuit layer, and including light emitting elements; a first inorganic insulating layer disposed on the light-emitting-element layer; a first organic insulating layer disposed on the first inorganic insulating layer, and defining trenches an area between the light emitting elements; a second inorganic insulating layer disposed on the first organic insulating layer; a second organic insulating layer disposed on the second inorganic insulating layer; and a plurality of air cavities disposed in the trenches between the second inorganic insulating layer and the second organic insulating layer.

The electronic device may further include a hydrophobic layer disposed in the trenches and between the second inorganic insulating layer and the plurality of air cavities, wherein the hydrophobic layer contacts the second inorganic insulating layer in the trenches.

### BRIEF DESCRIPTION OF THE DRAWINGS

FIG. 1 is a perspective view illustrating an embodiment of a display device in accordance with the present disclosure.

FIG. 2 is a sectional view taken along line I-I′ of FIG. 1.

FIG. 3 is a plan view illustrating an embodiment of the display panel of FIG. 2.

FIG. 4 is a plan view illustrating an embodiment of a sensing panel of FIG. 2.

FIG. 5 is a plan view illustrating an embodiment of some sub-pixels of FIG. 3.

FIG. 6 is a sectional view taken along line II-II′ of FIG. 5.

FIGS. 7 and 8 are plan views illustrating an example of air cavities according to positions thereof in the display panel of FIG. 3.

FIG. 9 is another sectional view taken along line II-II′ of FIG. 5.

FIG. 10 is a flowchart illustrating a method of fabricating the display device in accordance with an embodiment of the present disclosure.

FIGS. 11 to 17 are diagrams illustrating an example of a method of fabricating the display device of FIG. 10.

FIG. 18 is a schematic block diagram illustrating an electronic device including a display device in accordance with an embodiment.

### DETAILED DESCRIPTION

Hereinafter, embodiments of the present disclosure will be described in detail with reference to the attached drawings. In the following description, parts required for understanding of operations in accordance with the present disclosure will be described, and explanation of the other parts may be omitted. Accordingly, the present disclosure is not limited to embodiments set forth herein. That is, embodiments may be provided so that the present disclosure will be thorough and complete, and will fully convey the technical spirit of the disclosure to those skilled in the art.

It will be understood that when an element is referred to as being “coupled” or “connected” to another element, the element can be directly coupled or connected to the other element or indirectly coupled or connected to the other element with intervening elements therebetween. The terminology used herein is for the purpose of describing particular embodiments only and is not intended to be limiting. In the specification, when an element is referred to as “comprising” or “including” a component, it does not preclude another component, and the element may further include other components unless the context clearly indicates otherwise. The phrases “at least one of X, Y, and Z” and “at least one selected from the group consisting of X, Y, and Z” may be construed as X only, Y only, Z only, or any combination of two or more of X, Y, and Z (for instance, XYZ, XYY, YZ, and ZZ). As used herein, the term “and/or” can include any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned upside down, elements described as “below” or “beneath” other elements or features may then be oriented “above” the other elements or features. Thus, the term “below” can encompass both an orientation of above and below. Furthermore, the device may be otherwise oriented (e.g., rotated 90 degrees or at other orientations), and, as such, the spatially relative descriptors used herein interpreted accordingly.

Herein, various embodiments will be described with reference to drawings that are schematic illustrations. As such, variations from the shapes of the illustrations as a result, for example, of manufacturing techniques and/or tolerances, may be expected. Therefore, embodiments disclosed herein should not be construed as limited to the particular illustrated shapes of regions, but are to include deviations in shapes that result from, for instance, manufacturing. As such, the shapes illustrated in the drawings may not illustrate the actual shapes of regions of a device, and, as such, are not intended to be limiting.

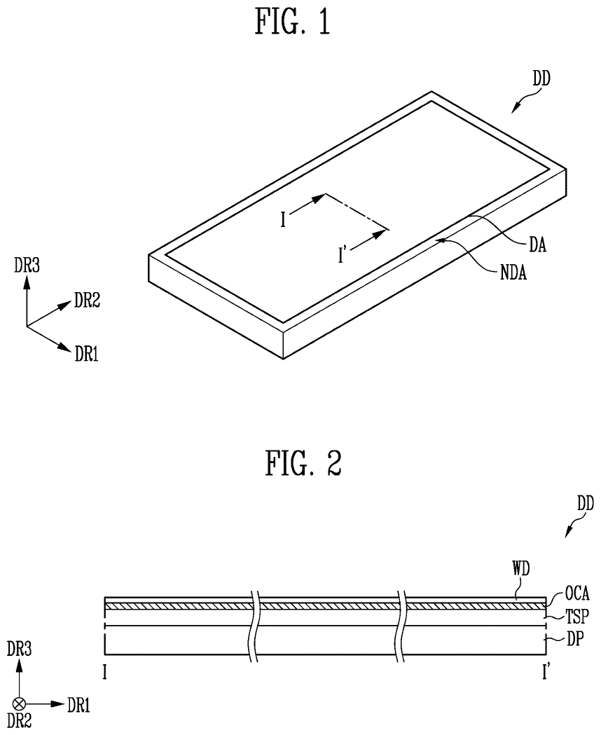

FIG. 1 is a perspective view illustrating an embodiment of a display device DD in accordance with the present disclosure.

Referring to FIG. 1, the display device DD may be an electronic device having a display surface. The display surface may be provided on a surface thereof. The electronic device may be, for example, a smartphone, a television, a tablet PC, a mobile phone, a video phone, an electronic reader, a desktop PC, a laptop PC, a netbook computer, a workstation, a server, a PDA, a portable multimedia player (PMP), an MP3 player, a medical appliance, a camera, or a wearable device.

The display device DD may be provided in various forms, for example, in the form of a rectangular plate having two pairs of parallel sides, but the present disclosure is not limited thereto. Although FIG. 1 illustrates that the display device DD may have an angled corner formed of linear lines, the present disclosure is not limited thereto. For example, the display device DD provided in the form of a rectangular plate may have a rounded shape at a corner where any two sides meet.

For the sake of convenience in explanation, FIG. 1 illustrates an example the display device DD may have a rectangular form with a pair of long sides and a pair of short sides. A direction in which the long sides extend may refer to a second direction DR2, a direction in which the short sides extend may refer to a first direction DR1, and a direction perpendicular to the first direction DR1 and the second direction DR2 may be referred to as a third direction DR3.

In an embodiment of the present disclosure, at least a portion of the display device DD may have flexibility, and the display device may be folded or bent at the portion having the flexibility.

The display device DD may include a display area DA and a non-display area NDA. The display area DA may be configured to display an image, and the non-display area NDA disposed on at least one side of the display area DA. The non-display area NDA may be an area in which no image may be displayed, and may be disposed around the display area DA. However, embodiments are not limited to the aforementioned example. For example, the shape of the display area DA and the shape of the non-display area NDA may be designed relative to each other.

FIG. 2 is a sectional view taken along line I-I′ of FIG. 1.

Referring to FIG. 2, the display device DD may include a display panel DP, a sensing panel TSP (or a touch sensor), and a window WD.

The display panel DP may display an image through the display area DA (refer to FIG. 1). A self-emissive display panel, such as an organic light emitting display panel (OLED panel) using an organic light emitting diode as a light emitting element, a subminiature light emitting diode (nano-scale LED) display panel using a subminiature LED as a light emitting element, or a quantum dot organic light emitting display panel (QD OLED panel) using a quantum dot and an organic light emitting diode, may be used as the display panel DP. In addition, a non-emissive display panel such as a liquid crystal display (LCD) panel, an electrophoretic display (EPD) panel, or an electro-wetting display (EWD) panel may be used as the display panel DP. In case that the non-emissive display panel is used as the display panel DP, the display device DD may include a backlight unit configured to supply light to the display panel DP.

The sensing panel TSP may be disposed on the display panel DP. The sensing panel TSP may receive a touch input from a user. The sensing panel TSP may sense the touch input in a mutual capacitance scheme, or may sense the touch input in a self-capacitance scheme.

The window WD may be disposed on the display panel DP and the sensing panel TSP to protect an exposed surface. The window WD may protect the display panel DP and the sensing panel TSP from external impacts. The window WD may provide an input surface and/or a display surface to the user. The window WD may be joined with the sensing panel TSP of the display device DD by an optically transparent adhesive (or bonding) agent OCA.

The window WD may have a single layer or a multilayer structure selected from among a glass substrate, a plastic film, or a plastic substrate. The multilayer structure may be formed through a successive process or an adhesion process using an adhesive layer. The window WD may be entirely or partially flexible at one or more portions thereof.

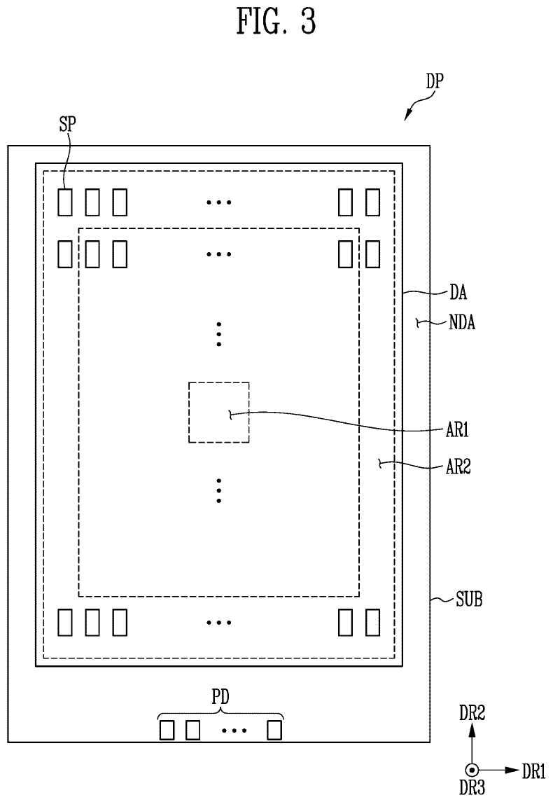

FIG. 3 is a plan view illustrating an embodiment of the display panel DP of FIG. 2.

Referring to FIG. 3, the display panel DP may include a substrate SUB, sub-pixels SP, and pads PD.

The sub-pixels SPX may be disposed in the display area DA on the substrate SUB. The sub-pixels SP may be arranged in the form of a matrix along a first direction DR1 and a second direction DR2 intersecting with the first direction DR1. For example, the sub-pixels SP may be arranged in a zigzag pattern in the first direction DR1 and the second direction DR2. For example, the sub-pixels SP may include an arrangement of subpixels of varying sizes. The arrangement structure of the sub-pixels SP is not limited, and the sub-pixels SP may be arranged in the display area DA in various structures and/or schemes.

Two or more sub-pixels among the sub-pixels SP may form a pixel. For example, three sub-pixels disposed adjacent to each other may form a single pixel capable of emitting light in various colors.

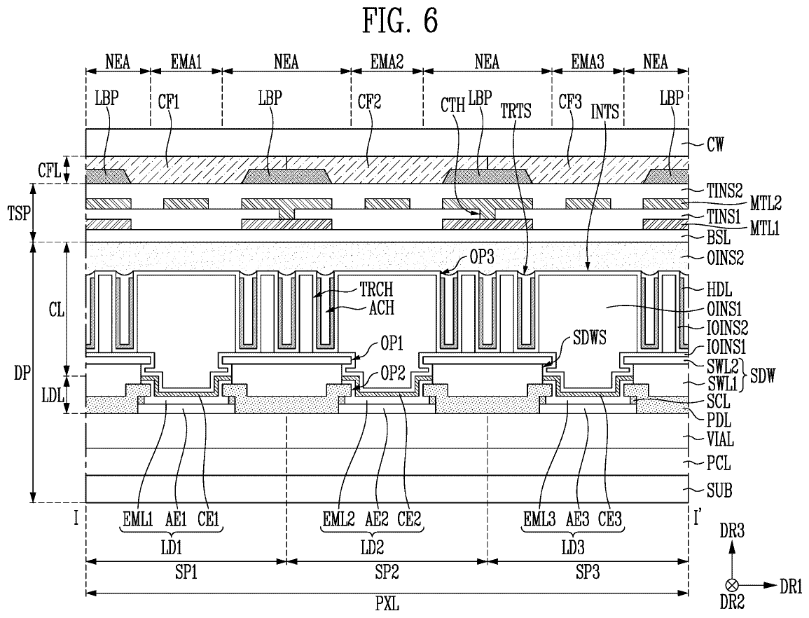

Each of the sub-pixels SP may be provided with light emitting elements LD1 to LD3 (refer to FIG. 6) as a light source, which may enable the sub-pixels SP to emit light in different colors. However, the color of light emitted from each of the sub-pixels SP may be changed in various ways.

Components for controlling the sub-pixels SP may be disposed in the non-display area NDA on the substrate SUB. For example, at least one driving circuit component (e.g., at least one of the scan driver or the data driver), lines, and/or pads connected to the sub-pixels SP may be disposed in the non-display area NDA.

At least one of the driving circuit components for driving the display panel DP may be integrated in the non-display area NDA on the display panel DP. For example, the scan driver may be mounted on the display panel DP and disposed in the non-display area NDA. As another example, the scan driver may be implemented as an integrated circuit that may be separate from the display panel DP.

The pads PD may be disposed in the non-display area NDA on the substrate SUB. The pads PD may be electrically connected to the sub-pixels SP through the lines. The pads PD may interface the display panel DP with other components of the display device DD (refer to FIG. 1). In embodiments, voltages and signals required for the operation of the components included in the display panel DP may be provided from a driver integrated circuit through the pads PD. For example, the data lines may be connected to the driver integrated circuit through the pads PD. For instance, power voltages may be received from the driver integrated circuit through the pads.

In embodiments, a circuit board may be electrically connected to the pads PD by a conductive adhesive component such as an anisotropic conductive film. Here, the circuit board may be a flexible printed circuit board (FPCB) or flexible film that is made of flexible material.

In embodiments, the display area DA may have various shapes. The display area DA may have a closed-loop shape, including linear and/or curved sides. For example, the display area DA may have shapes such as a polygon, a circle, a semicircle, and an ellipse.

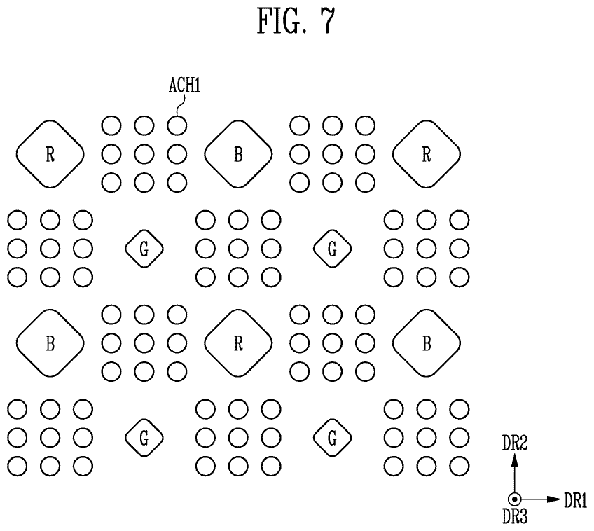

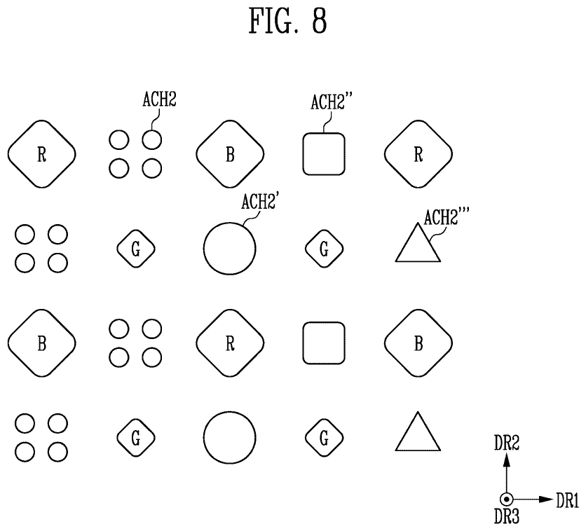

In an embodiment, the display area DA of the display panel DP may include a first area AR1 where first air cavities may be defined, and a second area AR2 where second air cavities may be device. The first area AR1 may be an area at or adjacent to a center portion of the display area DA. The second area AR2 may be an area adjacent to the non-display area NDA. Air cavities may be disposed at different densities in the first area AR1 and the second area AR2. For example, the air cavities in the first and second areas AR1 and AR2 may differ from each other in terms of shape and/or number. A detailed description will be provided below with reference to FIG. 7 and FIG. 8.

In embodiments, the display panel DP may have a planar display surface. In embodiments, the display panel DP may have a display surface that is at least partially rounded. In embodiments, the display panel DP is bendable, foldable, or rollable. In the aforementioned cases, the display panel DP and/or the substrate SUB may include materials having flexible properties.

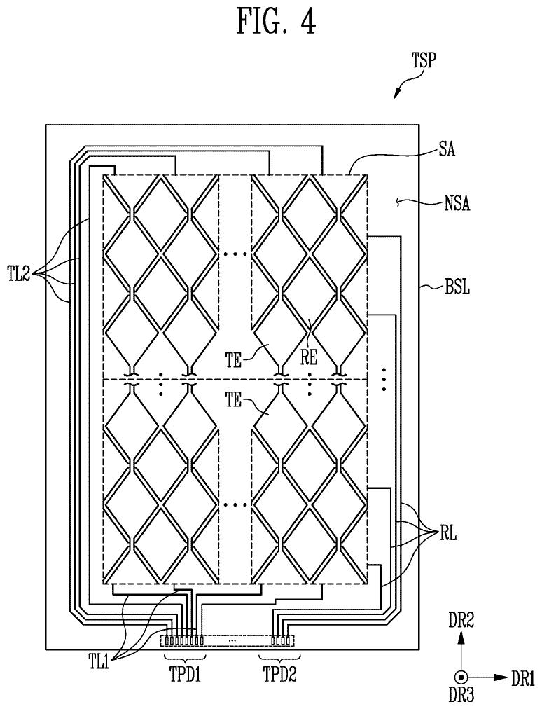

FIG. 4 is a plan view illustrating an embodiment of the sensing panel TSP of FIG. 2.

Referring to FIG. 4, the sensing panel TSP may include a sensing area SA formed to sense a touch from the user, and a non-sensing area NSA formed around the sensing area SA. The sensing area SA may overlap the display area DA (refer to FIG. 3). The non-sensing area NSA may overlap the non-display area NDA (refer to FIG. 3).

First touch electrodes TE may be arranged in the second direction DR2, and may be electrically connected to each other. Second touch electrodes RE may be arranged in the first direction DR1 intersecting with the second direction DR2, and may be electrically connected to each other. The first touch electrodes TE1 and the second touch electrodes TE2 may be electrically separated from each other. The first touch electrodes TE and the second touch electrodes RE may be disposed to be spaced apart from each other.

For example, the first touch electrodes TE that are adjacent to each other in the second direction DR2 may be electrically connected to each other, and the first touch electrodes TE that are adjacent to each other in the first direction DR1 may be insulated from each other. Furthermore, the second touch electrodes RE that are adjacent to each other in the first direction DR1 may be electrically connected to each other, and the second touch electrodes RE that are adjacent to each other in the second direction DR2 may be electrically insulated from each other. A mutual capacitance may be formed at intersections between the first touch electrodes TE and the second touch electrodes RE. It may be possible to determine whether a touch from the user is present by sensing a voltage charged in the mutual capacitance.

The first touch electrodes TE and the second touch electrodes RE may be formed in a mesh or net-like pattern. In this case, the luminance of light emitted from the sub-pixels SP (refer to FIG. 3) may be emitted to outside the display device DD. For example, a presence of the first touch electrodes TE and the second touch electrodes RE may not deteriorate the luminance of light emitted from the sub-pixels SP. For example, the mesh structure of the first touch electrodes TE and the second touch electrodes RE may be disposed to overlap the non-emission area NEA (refer to FIG. 6).

In an embodiment, sensing pads TPD1 and TPD2 and sensing lines TL1, TL2, and RL may be disposed in the non-sensing area NSA.

The sensing pads TPD1 and TPD2 may be disposed on a side of the non-sensing area NSA. The sensing pads TPD1 and TPD2 may include first sensing pads TPD1 and second sensing pads TPD2.

The sensing lines TL1, TL2, and RL may include driving lines TL1 and TL2 connected to the first touch electrodes TE, and detection lines RL connected to the second touch electrodes RE.

Referring to FIG. 4, the driving lines TL1 and TL2 may include first driving lines TL1 connected to the first touch electrodes TE that are disposed on a first side of the sensing area SA, and second driving lines TL2 connected to the first touch electrodes TE that are disposed on a second side of the sensing area SA. Here, the first side of the sensing area SA may refer to a lower side of the sensing area SA, and the second side of the sensing area SA may refer to an upper side of the sensing area SA. The upper side and the lower side of the sensing area SA may be opposite to each other. For example, among the first touch electrodes TE connected to each other in the second direction DR2, the first touch electrodes TE that are disposed on a lower side end may be connected to the first driving lines TL1. Among the first touch electrodes TE connected to each other in the second direction DR2, the first touch electrodes TE that are disposed on an upper side end may be connected to the second driving lines TL2. The second driving lines TL2 may be connected to the first touch electrodes TE on the upper side of the sensing area SA via the left side of the sensing area SA. First ends of the driving lines TL1 and TL2 may be connected to the first touch electrodes TE. Second ends of the driving lines TL1 and TL2 may be connected to the first sensing pads TPD1.

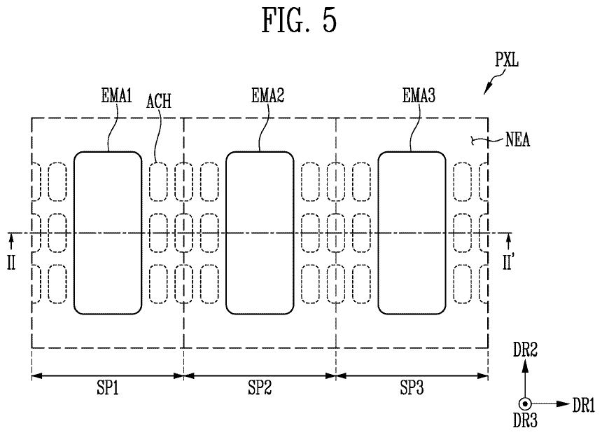

The second touch electrodes RE that are disposed on a side of the sensing area SA may be connected to the detection lines RL. For example, as illustrated in FIG. 5, among the second touch electrodes RE electrically connected to each other in the first direction DR1, the second touch electrodes RE that are disposed on a right side may be connected to the detection lines RL. First ends of the detection lines RL may be connected to the second touch electrodes RE. Second ends of the detection lines RL may be connected to the second sensing pads TPD2. However, embodiments are not limited to the aforementioned example.

FIG. 5 is a plan view illustrating an embodiment of some of the sub-pixels of FIG. 3.

Referring to FIG. 3 and FIG. 5, each pixel PXL may include first to third sub-pixels SP1 to SP3 arranged in the first direction DR1.

The first sub-pixel SP1 may include a first emission area EMA1 and a non-emission area NEA formed around the first emission area EMA1. The second sub-pixel SP2 may include a second emission area EMA2 and a non-emission area NEA formed around the second emission area EMA2. The third sub-pixel SP3 may include a third emission area EMA3 and a non-emission area NEA formed around the third emission area EMA3.

The first emission area EMA1 may be an area where light is emitted from a light emitting element corresponding to the first sub-pixel SP1. The second emission area EMA2 may be an area where light is emitted from a light emitting element corresponding to the second sub-pixel SP2. The third emission area EMA3 may be an area where light is emitted from a light emitting element corresponding to the third sub-pixel SP3. The emission areas EMA1 to EMA3 may be understood as corresponding to openings OP2 (refer to FIG. 6) of a pixel defining layer PDL for the first to third sub-pixels SP1 to SP3, respectively.

In embodiments, a plurality of air cavities ACH may be formed in the non-emission area NEA between the first to third emission areas EMA1 to EMA3.

The air cavities ACH may be formed in the non-emission area NEA where the light emitting elements LD1 to LD3 (refer to FIG. 6) are not disposed. In the non-emission area NEA, the air cavities ACH may be arranged in the form of a matrix in the first direction DR1 and the second direction DR2 intersecting with the first direction DR1. For example, the air cavities ACH may be arranged in groups of three in the first direction DR1 between the first and second emission areas EMA1 and EMA2, and also in groups of three in the second direction DR2. The air cavities ACH may be arranged in groups of three in the first direction DR1 between the second and third emission areas EMA2 and EMA3, and also in groups of three in the second direction DR2. Although in FIG. 5 an example has been illustrated in which nine air cavities ACH are disposed in the non-emission area NEA between the first and second emission areas EMA1 and EMA2 and in the non-emission area NEA between the second and third emission areas EMA2 and EMA3, the number of air cavities ACH disposed in the corresponding areas is not limited thereto.

In an embodiment, the density at which the air cavities ACH are disposed in the non-emission area NEA between the light emitting elements may increase as the positions of the air cavities ACH are closer to a center portion of the display area DA. For example, a number of air cavities ACH per unit surface area may increase as the positions of the air cavities ACH are closer to a center portion of the display area DA. The number of air cavities ACH per unit surface area may decrease as the positions of the air cavities ACH are closer to the non-display area NDA. For example, in each pixel included in the first area AR1 adjacent to a center portion of the display area DA, four air cavities ACH may be disposed between the first and second emission areas EMA1 and EMA2. On the other hand, in each pixel included in the second area AR2 adjacent to the non-display area NDA, two air cavities ACH may be disposed between the first and second emission areas EMA1 and EMA2. In other words, the number of air cavities ACH per unit surface area may vary depending on the position in the display area DA.

FIG. 6 is a sectional view taken along line II-II′ of FIG. 5.

Referring to FIG. 5 and FIG. 6, the display device DD may include a substrate SUB, a pixel circuit layer PCL, a light-emitting-element layer LDL, an encapsulation layer CL, a sensing panel TSP (or a touch sensor), a color filter layer CFL, and a window WD. The encapsulation layer CL may include a first inorganic insulating layer IOINS1, a first organic insulating layer OINS1, a second inorganic insulating layer IOINS2, and a second organic insulating layer OINS2. The sensing panel TSP may include a touch base layer BSL, a first conductive pattern MTL1, a first touch insulating layer TINS1, a second conductive pattern MTL2, and a second touch insulating layer TINS2. The first and second conductive patterns MTL1 and MTL2 may be provided as the first and second touch electrodes TE and RE (refer to FIG. 4).

The substrate SUB may include a semiconductor substrate. For example, the substrate SUB may include a silicon bulk wafer, or an epitaxial wafer. The epitaxial wafer may include a crystalline material layer, i.e., an epitaxial layer, grown on a bulk substrate through an epitaxial process. The substrate SUB is not limited to the bulk wafer or the epitaxial wafer, but may be formed using various wafers such as a polished wafer, an annealed wafer, and a silicon on insulator (SOI) wafer.

The pixel circuit layer PCL may be disposed on the substrate SUB, and may include pixel circuits provided to drive the sub-pixels SP formed by the light-emitting-element layer LDL. The pixel circuit layer PCL may include circuit elements including a plurality of transistors, and signal lines connected to the transistors.

The light-emitting-element layer LDL may be disposed on the pixel circuit layer PCL. The light-emitting-element layer LDL may include the light emitting elements LD1 to LD3 and the pixel defining layer PDL. The light emitting elements LD1 to LD3 may be respectively positioned in the sub-pixels SP, and each may be connected to at least one transistor (not illustrated).

In an embodiment, the light emitting elements LD1 to LD3 may respectively include anode electrodes AE1 to AE3, emission layers EML1 to EML3, and cathode electrodes CE1 to CE3.

The anode electrodes AE1 to AE3 may supply holes to the emission layers EML1 to EML3. For example, the anode electrodes AE1 to AE3 may include a metal layer made of silver (Ag), magnesium (Mg), aluminum (Al), platinum (Pt), palladium (Pd), gold (Au), nickel (Ni), neodymium (Nd), iridium (Ir), chromium (Cr), or an alloy thereof, and/or indium tin oxide (ITO), indium zinc oxide (IZO), zinc oxide (ZnO), or indium tin zinc oxide (ITZO).

The cathode electrodes CE1 to CE3 may supply electrons to the emission layers EML1 to EML3. For example, the cathode electrodes CE1 to CE3 may include silver (Ag), titanium (Ti), aluminum (Al), molybdenum (Mo), or an alloy (Ag: Mg) of silver (Ag) and magnesium (Mg).

The emission layers EML1 to EML3 may be disposed on the anode electrodes AE1 to AE3. The emission layers EML1 to EML3 may include a first emission layer EML1 provided to display a first color, a second emission layer EML2 provided to display a second color, and a third emission layer EML3 provided to display a third color. For example, the first color may be red, the second color may be green, and the third color may be blue, but the present disclosure is not limited thereto.

In the emission layers EML1 to EML3, holes supplied from the anode electrodes AE1 to AE3 and electrons supplied from the cathode electrodes CE1 to CE3 may be recombined with each other, thereby forming excitons. The formed excitons may be stabilized while emitting light. The emission layers EML1 to EML3 may include materials that emit specific colors of light.

The pixel defining layer PDL may be disposed to overlap the non-emission area NEA. The pixel defining layer PDL may include organic insulating layers including organic material. The organic material may include one or more of acryl resin, epoxy resin, phenolic resin, polyamide resin, or polyimide resin.

The pixel defining layer PDL may include light absorption material. The pixel defining layer PDL may be coated with light absorbent, thus functioning to absorb light from the outside. For example, the pixel defining layer PDL may include carbon-based black pigment. However, the present disclosure is not limited to the aforementioned example. For example, the pixel defining layer PDL may include opaque metal such as chromium (Cr), molybdenum (Mo), an alloy (MoTi) of molybdenum and titanium, tungsten (W), vanadium (V), niobium (Nb), tantalum (Ta), manganese (Mn), cobalt (Co), or nickel (Ni), having high light absorptivity.

The pixel defining layer PDL may be disposed on a via insulating layer VIAL. For example, the pixel defining layer PDL may include second openings OP2 through which at least portions of the anode electrodes AE1 to AE3 are exposed. Each of the second openings OP2 may have an undercut structure. The undercut structure of the pixel defining layer PDL may be formed by a sacrificial layer SCL.

First and second metal layers SWL1 and SWL2 may be disposed on the pixel defining layer PDL. For example, the first metal layer SWL1 may be disposed on the pixel defining layer PDL. The second metal layer SWL2 may be disposed on the first metal layer SWL1. The first and second metal layers SWL1 and SWL2 may be provided as sidewall structures SDW. In this case, the second metal layer SWL2 may have a width greater than that of the first metal layer SWL1. The second metal layer SWL2 may protrude from the first metal layer SWL1 in the first direction DR1 and a direction opposite to the first direction DR1. The first and second metal layers SWL1 and SWL2 may include metallic material such as copper (Cu), molybdenum (Mo), aluminum (Al), silver (Ag), chromium (Cr), tantalum (Ta), or titanium (Ti), or a metal alloy.

The first and second metal layers SWL1 and SWL2 may have first openings OP1 through which at least portions of the cathode electrodes CE1 to CE3 are exposed. Each of the first openings OP1 may have an undercut structure. The undercut structure of the first openings OP1 may enhance adhesive force of the first organic insulating layer IONS1, thus mitigating a peeling phenomenon.

The emission layers EML1 to EML3 may be disposed on the anode electrodes AE1 to AE3. The emission layers EML1 to EML3 may contact the anode electrodes AE1 to AE3. The emission layers EML1 to EML3 may contact the undercut structure of the pixel defining layer PDL. The emission layers EML1 to EML3 may contact the sacrificial layer SCL. The emission layers EML1 to EML3 may contact side surfaces SDWS of the sidewall structures SDW.

The cathode electrodes CE1 to CE3 may be disposed on the emission layers EML1 to EML3. For example, the cathode electrodes CE1 to CE3 may cover overall areas of the emission layers EML1 to EML3. The cathode electrodes CE1 to CE3 may contact the emission layers EML1 to EML3. The cathode electrodes CE1 to CE3 may contact the side surfaces SDWS of the sidewall structures SDW.

The first inorganic insulating layer INS1 may be disposed on the light-emitting-element layer LDL. The first inorganic insulating layer IOINS1 may prevent penetration of external moisture and oxygen. For example, the first inorganic insulating layer IOINS1 may be disposed on the cathode electrodes CE to CE3. The first inorganic insulating layer IOINS1 may cover overall areas of the cathode electrodes CE1 to CE3 and the sidewall structures SDW. The first inorganic insulating layer IOINS1 may include inorganic material. One or more of inorganic insulating materials such as silicon oxide, silicon nitride, or silicon oxynitride may be selected as the inorganic material.

The first organic insulating layer OINS1 may be disposed on the first inorganic insulating layer IOINS1. Trenches TRCH may be formed in the first organic insulating layer OINS1. The first organic insulating layer OINS1 may include organic material. One or more of organic insulating materials such as a polyacryl compound, a polyimide compound, a fluorocarbon compound such as Teflon, or a benzocyclobutene compound may be used as the organic material.

Air cavities ACH may be provided in the trenches TRCH. The air cavities ACH may refer to a structure in which air is trapped. For example, upper surfaces TRTS of the air cavities ACH in the trenches TRCH may be blocked by the second organic insulating layer OINS2, and remaining surfaces thereof may be blocked by hydrophobic layers HDL.

The permittivity of a vacuum or air is approximately 1. A vacuum or air may have a permittivity lower than that of organic material. As the air cavities ACH are provided in the trenches TRCH of the first organic insulating layer OINS1, a permittivity between the touch electrodes TE and RE and the cathode electrodes CE1 to CE3 may be reduced. For example, the organic materials included in the first organic insulating layer OINS1 may have a permittivity ranging from about 3.0 to 3.5. The first organic insulating layer OINS1 having the air cavities ACH may have a permittivity of about 2.5 or less. As such, since the permittivity in the air cavities ACH is less than that of the organic materials, the permittivity of the first organic insulating layer OINS1 may be reduced by forming the air cavities ACH in the first organic insulating layer OINS1. The reduction in the permittivity may lead to a decrease in the capacitance between the touch electrodes TE and RE and the cathode electrodes CE1 to CE3, which may reduce noise in signals generated touch and improve the touch sensitivity.

In embodiments, the trenches TRCH and the air cavities ACH in the trenches TRCH may be formed in the non-emission area NEA between the light emitting elements LD1 to LD3. The refractive index of light may differ between air and organic material. In the case where the air cavities ACH are formed in the emission areas EMA1 to EMA3, light emitted from the emission layers EML1 to EML3 may be refracted. Therefore, the air cavities ACH may be formed in the non-emission area NEA. The air cavities ACH may be formed to overlap the pixel defining layer PDL and the sidewall structures SDW.

In an embodiment, the density of the air cavities ACH may vary depending on the positions thereof in the display area DA (refer to FIG. 3). For example, the number of air cavities ACH per unit surface area may increase as the positions of the air cavities ACH are closer to a center portion of the display area DA. The number of air cavities ACH per unit surface area may decrease as the positions of the air cavities ACH are closer to the non-display area NDA. Although in FIG. 6 an example has been illustrated in which three air cavities ACH are arranged in the first direction DR1 in the non-emission area NEA between the first and second emission areas EMA1 and EMA2 and in the non-emission area NEA between the second and third emission areas EMA2 and EMA3, the present disclosure is not limited thereto. For example, two air cavities ACH may be disposed in each of the corresponding areas.

The second inorganic insulating layer IOINS2 may be disposed on the first organic insulating layer OINS1. The second inorganic insulating layer IOINS2 may include inorganic material. One or more of inorganic insulating materials such as silicon oxide, silicon nitride, or silicon oxynitride may be selected as the inorganic material.

The second inorganic insulating layer IOINS2 may cover an overall area of the first organic insulating layer OINS1. During a process of forming the second inorganic insulating layer IOINS2 on the first organic insulating layer OINS1, the second inorganic insulating layer IOINS2 may be deposited in the trenches TRCH of the first organic insulating layer OINS1. The second inorganic insulating layer IOINS2 may contact inner surfaces of the trenches TRCH.

In the trenches TRCH, the hydrophobic layers HDL may be disposed on the second inorganic insulating layer IOINS2. The hydrophobic layers HDL may be disposed between the second inorganic insulating layer IOINS2 and the air cavities ACH. The hydrophobic layers HDL may contact the second inorganic insulating layer IOINS2.

The hydrophobic layers HDL may include vertical portions disposed on sidewalls of the trenches TRCH, and bottom portions connecting the vertical portions and disposed on the lower surfaces TRDS of the trenches TRCH. The hydrophobic layers HDL may have a U shape forming a channel in the second direction DR2. For example, the bottom portions of the hydrophobic layers HDL may be exposed to an area above. The hydrophobic layers HDL may enclose the air cavities ACH except for the upper surfaces TRTS of the air cavities ACH. A portion of the air cavities ACH may extend above the hydrophobic layers HDL in the trenches TRCH.

The hydrophobic layers HDL may include hydrophobic material. The hydrophobic layers HDL may include a fluorine compound. The hydrophobic layers HDL may be deposited using plasma gas or formed through a coating process. However, embodiments are not limited to the aforementioned example. For example, the hydrophobic layers HDL may include at least one of the following hydrophobic materials: manganese oxide (MnO₂) polystyrene, zinc oxide (ZnO) polystyrene, precipitated calcium carbonate, carbon nanotubes, or silica.

The hydrophobic layers HDL may have a contact angle of 90 degrees or more with respect to the second organic insulating layer OINS2. An affinity between the hydrophobic layers HDL and the second organic insulating layer OINS2 may be less than that between the second inorganic insulating layer IOINS2 and the second organic insulating layer OINS2. In other words, in the case where organic material for forming the second organic insulating layer OINS2 is applied to each of the hydrophobic layers HDL and the second inorganic insulating layer IOINS2, the contact angle of the organic material applied to the hydrophobic layers HDL may be greater than that of the organic material applied to the second inorganic insulating layer IOINS2. Consequently, the second organic insulating layer OINS2 may flow over the second inorganic insulating layer IOINS2, but may cohere to the hydrophobic layers HDL due to internal attractive forces rather than flowing over the hydrophobic layers HDL. Since the hydrophobic layers HDL having the aforementioned characteristics are disposed in the trenches TRCH, organic material may be prevented from being introduced into the trenches TRCH. As a result, the air cavities ACH may be more effectively formed.

The second organic insulating layer OINS2 may be disposed on the second inorganic insulating layer IOINS2. The second organic insulating layer OINS2 may be disposed on a surface INTS of the second inorganic insulating layer IOINS2 in the third direction DR3. The second organic insulating layer OINS2 may have a substantially even upper surface. The second organic insulating layer OINS2 may cover third openings OP3 of the trenches TRCH due to low surface energy in the trenches TRCH. For example, the second organic insulating layer OINS2 may cap the third openings OP3 of the trenches TRCH.

The sensing panel TSP may be disposed on the second organic insulating layer OINS2. The touch base layer BSL, the first conductive patterns MTL1, the first touch insulating layer TINS1, the second conductive patterns MTL2, and the second touch insulating layer TINS2 may be sequentially disposed on the second organic insulating layer OINS2 in the third direction DR3.

The touch electrodes TE and RE (refer to FIG. 4) may be formed of the first conductive patterns MTL1 and the second conductive patterns MTL2 that are disposed on the second organic insulating layer OINS2.

Each of the first and second conductive patterns MTL1 and MTL2 may include metal or transparent conductive material. The metal may include aluminum (Al), titanium (Ti), copper (Cu), molybdenum (Mo), silver (Ag), or an alloy thereof. The transparent conductive material may include transparent conductive oxide such as indium tin oxide (ITO), indium zinc oxide (IZO), zinc oxide (ZnO), or indium tin zinc oxide (ITZO), a conductive polymer such as PEDOT, metal nanowires, or graphene.

The first touch insulating layer TINS1 may include an organic insulating layer including organic material, or an inorganic insulating layer including inorganic material. Some of the second conductive patterns MTL2 may be electrically connected to the first conductive patterns MTL1 through contact holes CTH passing through the first touch insulating layer TINS1.

The first conductive patterns MTL1 may electrically connect some of the second conductive patterns MTL2. For example, some second conductive patterns MTL2 that are connected by the first conductive patterns MTL1 may form the first touch electrodes TE, while other second conductive patterns MTL2 may form the second touch electrodes RE. As another example, some second conductive patterns MTL2 that are connected by the first conductive patterns MTL1 may form the second touch electrodes RE, while other second conductive patterns MTL2 may form the first touch electrodes TE.

The color filter layer CFL may be disposed on the second touch insulating layer TINS2. The color filter layer CFL may include first to third color filters CF1 to CF3 and light blocking patterns LBP.

The light blocking patterns LBP may be disposed to overlap the non-emission area NEA. For example, one of the light blocking patterns LBP may overlap the non-emission area NEA between the first and second emission areas EMA1 and EMA2. Another of the light blocking patterns LBP may overlap the non-emission area NEA between the second and third emission areas EMA2 and EMA3.

The window WD may be disposed on the color filter layer CFL. The window WD may be disposed on an overall area of the color filter layer CFL. The window WD may protect an exposed surface of the display device DD. The window WD may protect the display panel DP and the sensing panel TSP from external impacts. The window WD may provide an input surface and/or a display surface to the user.

FIG. 7 and FIG. 8 are plan views illustrating an example of the air cavities according to positions thereof in the display panel of FIG. 3.

Referring to FIG. 7 and FIG. 8, the light emitting elements may include first light emitting elements R configured to display a first color, second light emitting elements G configured to display a second color, and third light emitting elements B configured to display a third color. Here, embodiments of the present disclosure are not limited to a pixel structure illustrated in FIG. 7 and FIG. 8.

The first and second air cavities ACH1 and ACH2 may be disposed in the non-emission area where the light emitting elements R, G, and B are not disposed. In the non-emission area, the first and second air cavities ACH1 and ACH2 may be disposed at different densities. For example, the numbers of first and second air cavities ACH1 and ACH2 per surface area may be different from each other.

Referring to FIG. 3 and FIG. 7, the first air cavities ACH1 may be disposed in the first area AR1 adjacent to a center portion of the display area DA. For example, the first air cavities ACH1 may be disposed between the first light emitting elements R and the third light emitting elements B that are alternately arranged in the first direction DR1 and/or the second direction DR2. Furthermore, the first air cavities ACH1 may be disposed between the second light emitting elements G that are arranged in the first direction DR1 and/or the second direction DR2. When viewed in the third direction DR3, nine first air cavities ACH1 may be arranged in a 3×3 matrix pattern in each space between the light emitting elements.

Referring to FIG. 3 and FIG. 8, the second air cavities ACH2 may be disposed in the second area AR2 adjacent to the non-display area NDA. For example, the second air cavities ACH2 may be disposed between the first light emitting elements R and the third light emitting elements B that are alternately arranged in the first direction DR1 and/or the second direction DR2. Furthermore, the second air cavities ACH2 may be disposed between the second light emitting elements G that are arranged in the first direction DR1 and/or the second direction DR2. For example, when viewed in the third direction DR3, four second air cavities ACH2 may be arranged in a 2×2 matrix pattern in each space between the light emitting elements. As another example, when viewed in the third direction DR3, any one of second air cavities ACH2′ to ACH2′″ may be disposed in each space between the light emitting elements.

Referring to FIG. 7 and FIG. 8, a number of first air cavities per unit surface area may be equal to or greater than a number of second air cavities per unit surface area. For example, the density at which the air cavities are disposed may increase as the positions of the air cavities are closer to a center portion of the display area DA. For example, the number of air cavities per unit surface area may increase as the positions of the air cavities ACH are closer to a center portion of the display area DA. The number of air cavities per unit surface area may decrease as the positions of the air cavities ACH are closer to the non-display area NDA. In other words, the density at which the air cavities are disposed may increase in areas where user touch is more frequently detected. As the density of air cavities increases, the reduction in permittivity may increase, which can further enhance touch sensitivity.

In an embodiment, when viewed in the third direction DR3, a second air cavity ACH2′ may be disposed in each space between the light emitting elements. In this case, depending on the positions in the display area DA, the surface areas of the air cavities may differ from each other. For example, the surface areas of air cavities may increase as the positions of the air cavities ACH are closer to a center portion of the display area DA. The surface areas of air cavities may decrease as the positions of the air cavities ACH are closer to the non-display area NDA. In other words, the surface areas of the air cavities may increase in areas where user touch is more frequently detected.

The first and second air cavities ACH1 and ACH2 may have different shapes. For example, when viewed in the third direction DR3, each second air cavity ACH2″ may be disposed in a single rectangular shape. Alternatively, each second air cavity ACH2′″ may be disposed in a single triangular shape. Here, the shapes of the air cavities may be changed in various ways and are not particularly limited.

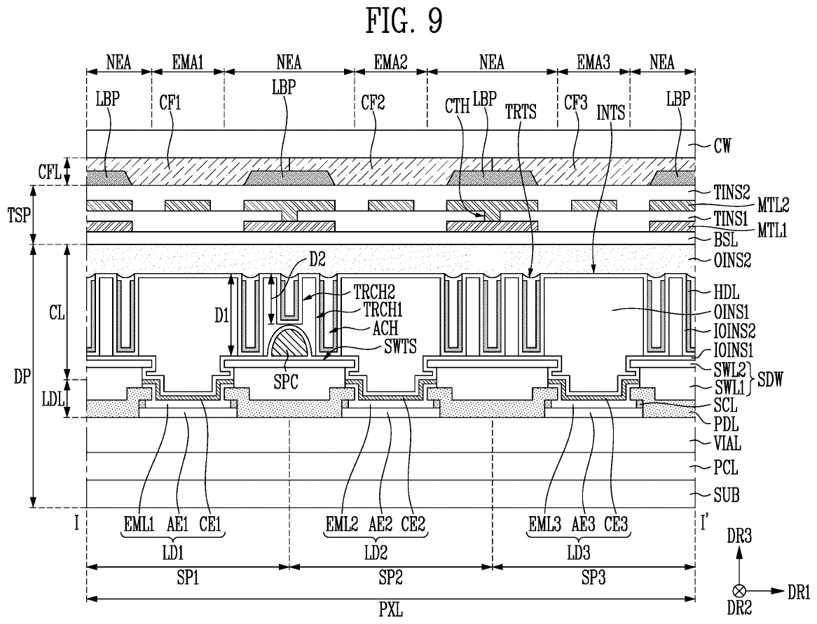

FIG. 9 is another sectional view taken along line II-II′ of FIG. 5.

Referring to FIG. 9, air cavities may have different depths. Description of content overlapping that described with reference to FIG. 6 may be omitted or simplified.

A spacer SPC may be disposed on the pixel defining layer PDL. The spacer SPC may be disposed in the non-emission area NEA between the light emitting elements LD1 to LD3. The spacer SPC may be provided to ensure that a mask used for depositing the emission layers EML1 to EML3 of the light emitting elements LD1 to LD3 is spaced apart from the light emitting elements LD1 to LD3. Here, although illustrated as the spacer SPC in FIG. 9, the present disclosure is not limited thereto. For example, instead of, or in addition to the spacer SPC, a structure may be disposed on the pixel defining layer PDL that may protrude beyond the light emitting elements LD1 to LD3. For example, a foreign substance added during a fabrication process may be used.

For example, the spacer SPC may be disposed between in the non-emission area NEA between the first light emitting element LD1 and the second light emitting element LD2. The spacer SPC may overlap one or more of the sidewall structures SDW and may overlap the pixel defining layer PDL. The spacer SPC may be disposed on a surface SWTS of any one of the sidewall structures SDW that is adjacent to the second organic insulating layer OINS2.

The first organic insulating layer OINS1 may include a first trench TRCH1 that does not overlap the spacer SPC, and a second trench TRCH2 that overlaps the spacer SPC. For example, the first trench TRCH1 may have a first depth D1 in the third direction DR3. The second trench TRCH2 may have a second depth D2 less than the first depth D1 in the third direction DR3. For example, the second depth D2 may account to a height of the spacer SPC. Overlapping the spacer SPC, the second trench TRCH2 may not have the same depth as the first trench TRCH1.

As such, the trenches TRCH1 and TRCH2 in the first organic insulating layer OINS1 may be formed to different depths in the first organic insulating layer OINS1 depending on the structure under the first organic insulating layer OINS1. The air cavities ACH defined in the trenches TRCH1 and TRCH2 may have different volumes depending on the trenches TRCH1 and TRCH2.

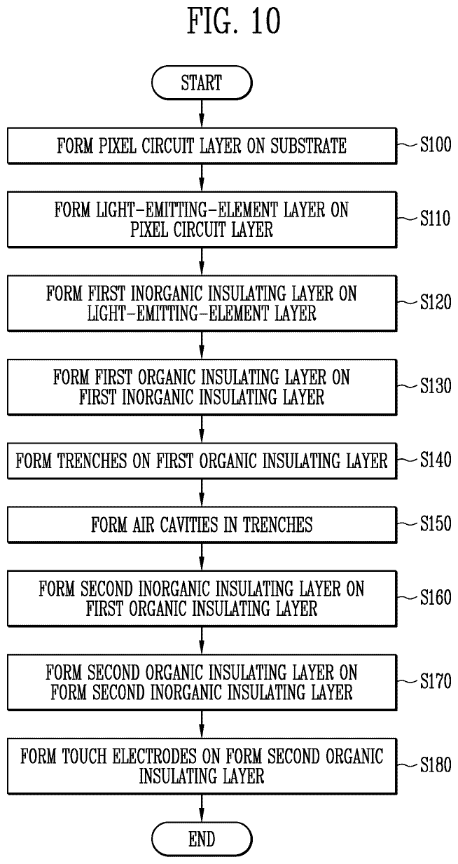

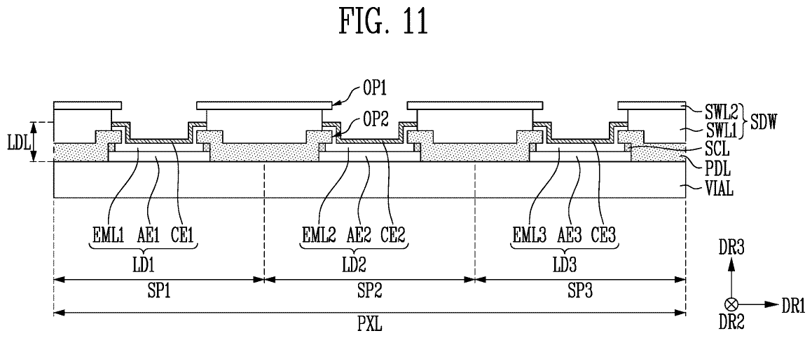

FIG. 10 is a flowchart illustrating a method of fabricating the display device in accordance with an embodiment of the present disclosure.

Referring to FIG. 10, a method of fabricating the display device may include step S100 of forming a pixel circuit layer on a substrate, step S110 of forming a light-emitting-element layer on the pixel circuit layer, step S120 of forming a first inorganic insulating layer on the light-emitting-element layer, step S130 of forming a first organic insulating layer on the first inorganic insulating layer, step S140 of forming trenches in the first organic insulating layer, step S150 of forming air cavities in the trenches, step S160 of forming a second inorganic insulating layer on the first organic insulating layer, step S170 of forming a second organic insulating layer on the second inorganic insulating layer, and step S180 of forming touch electrodes on the second organic insulating layer. Hereinafter, a method of fabricating the display device will be described in detail with reference to FIGS. 11 to 17.

FIGS. 11 to 17 are diagrams illustrating an example of a method of fabricating the display device of FIG. 10.

Hereinafter, a method of fabricating the display device described with reference to FIG. 6 will be described with reference to FIGS. 11 to 17. In the following description with reference to FIGS. 11 to 17, contents overlapping those described with reference to FIG. 6 may be omitted or simplified.

Referring to FIG. 11, the light-emitting-element layer including the first to third light emitting elements LD1 to LD3 may be formed on a via insulating layer VIAL. The via insulating layer VIAL may be provided as the base layer.

In embodiments, the anode electrodes AEl to AE3 may be formed on the via insulating layer VIAL. The sacrificial layer SCL may be formed on the anode electrodes AE1 to AE3. The pixel defining layer PDL may be formed on the via insulating layer VIAL to cover the anode electrodes AE1 to AE3 and the sacrificial layer SCL.

The first metal layer SWL1 and the second metal layer SWL2 may be sequentially formed on the pixel defining layer PDL. For example, the first metal layer SWL1 may be formed on the pixel defining layer PDL and the second metal layer SWL2 may be formed on the first metal layer SWL1. The first openings OP1 may be formed in the first and second metal layers SWL1 and SWL2. The first openings OP1 may be formed by patterning the first and second metal layers SWL1 and SWL2 using the photoresist pattern. The first openings OP1 may expose at least a portion of the pixel defining layer PDL that overlaps the anode electrodes AE1 to AE3. In other words, the first and second metal layers SWL1 and SWL2 having the first openings OP1 may form the sidewall structures SDW that overlap the pixel defining layer PDL.

The second openings OP2, which may be connected to the first openings OP1 and may expose portions of the sacrificial layer SCL, may be formed in the pixel defining layer PDL. For example, to form the second openings OP2, portions of the first and second metal layers SWL1 and SWL2 may be removed by a wet etching method, and a portion of the pixel defining layer PDL may be removed by a dry etching method. In this case, since the sacrificial layer SCL may cover the overall upper surfaces of the anode electrodes AE1 to AE3, the anode electrodes AE1 to AE3 may not be removed by the dry etching method. In other words, the sacrificial layer SCL may protect the anode electrodes AE1 to AE3 from etching by the dry etching method.

Thereafter, the sacrificial layer SCL exposed through the second openings OP2 may be partially removed by the wet etching method. The sacrificial layer SCL that is not removed may be disposed along peripheral portions of each of the anode electrodes AE1 to AE3. In a case that the sacrificial layer SCL is partially removed, each of the second openings OP2 may have an undercut structure.

The peripheral portions of each of the anode electrodes AE1 to AE3 may be upper surface of the anode electrodes AE1 to AE3. The peripheral portions of each of the anode electrodes AE1 to AE3 may be disposed at perimeters of the anode electrodes AE1 to AE3.

The emission layers EML1 to EM13 may be formed on the anode electrodes AE1 to AE3. For example, the emission layers EML1 to EML3 may be formed to contact protrusions of the pixel defining layer PDL in the second openings OP2 on the anode electrodes AE1 to AE3. The emission layers EML1 to EML3 may be injected into vacant space of the undercut structures of the second openings OP2.

The cathode electrodes CE1 to CE3 may be formed on the emission layers EML1 to EML3. The emission layers EML1 to EML3 and the cathode electrodes CE1 to CE3 may contact the side surfaces of the sidewall structures SDW. For example, the second metal layer SWL2 that forms the sidewall structures SDW may have a width greater than that of the first metal layer SWL1. The emission layers EML1 to EML3 and the cathode electrodes CE1 to CE3 may contact the side surfaces of the sidewall structures SDW formed of the first metal layer SWL1.

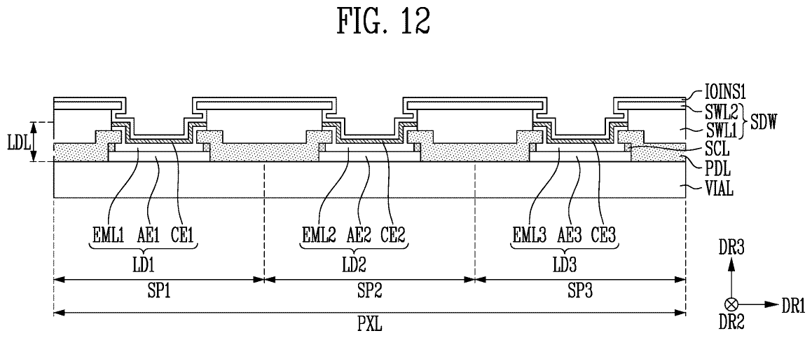

Referring to FIG. 12, the first inorganic insulating layer IOINS1 may be formed on the light-emitting-element layer LDL. The first inorganic insulating layer IOINS1 may be formed on the cathode electrodes CE1 to CE3 to cover the cathode electrodes CE1 to CE3 and the sidewall structures SDW. The first inorganic insulating layer IOINS1 may be formed to contact the cathode electrodes CE1 to CE3 and the sidewall structures SDW.

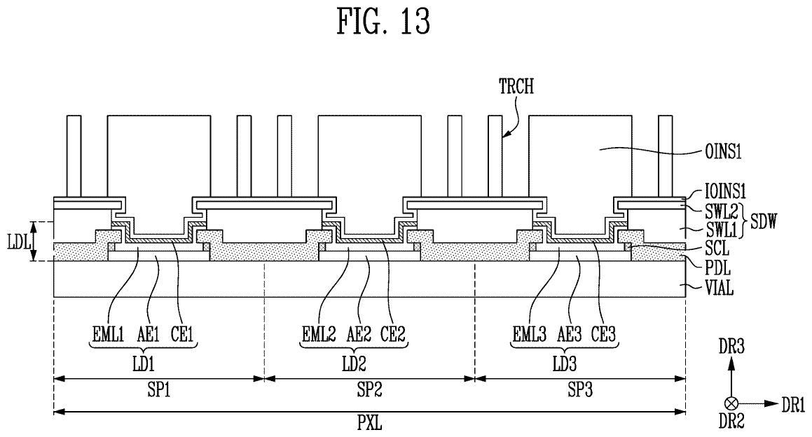

Referring to FIG. 13, the first organic insulating layer OINS1 may be formed on the first inorganic insulating layer IOINS1. The first organic insulating layer OINS1 may have the trenches TRCH. The trenches TRCH may extend in a direction opposite to the third direction DR3 in the area NEA (refer to FIG. 6) between adjacent ones of the first to third light emitting elements LD1 to LD3. The trenches TRCH may be formed to overlap the pixel defining layer PDL. For example, the trenches TRCH may be formed by removing portions of the first organic insulating layer OINS1 using a dry etching method. In detail, a photoresist pattern may be formed on the first organic insulating layer OINS1 to pattern the trenches TRCH. The first organic insulating layer OINS1 may be etching through a photolithography process. After the trenches TRCH are formed, the photoresist pattern may be removed.

While FIG. 13 depicts three trenches TRCH disposed overlapping each the pixel defining layer PDL in the first direction DR1, the number of trenches is illustrative and is not limiting. For example, the trenches TRCH may be arranged in groups of three in the first direction DR1 between adjacent ones of the first and second emission areas EMA1 and EMA2, and also in groups of three in the second direction DR2. Although in FIG. 13 an example has been illustrated in which three trenches TRCH may be disposed overlapping each the pixel defining layer PDL, the number of trenches TRCH is not limited thereto.

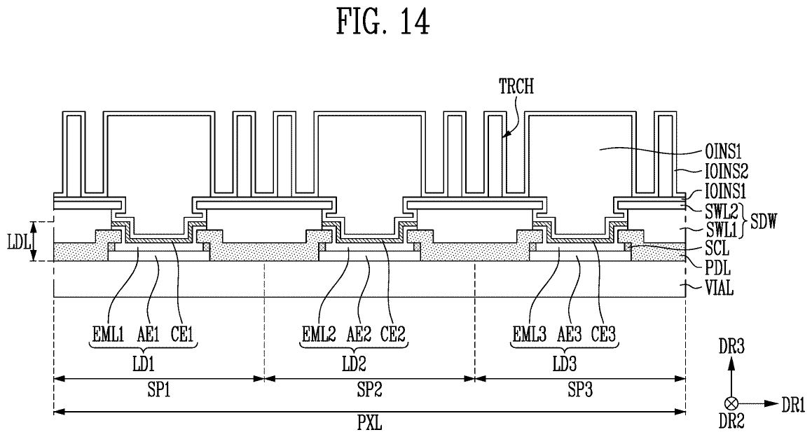

Referring to FIG. 14, the second inorganic insulating layer IOINS2 may be formed on the first organic insulating layer OINS1. The second inorganic insulating layer IOINS2 may be formed to cover the first organic insulating layer OINS1. The second inorganic insulating layer IOINS2 may be formed by chemical vapor deposition (CVD) or atomic layer deposition (ALD). The second inorganic insulating layer IOINS2 may be formed to cover the respective inner surfaces of the trenches TRCH of the first organic insulating layer OINS1. The second inorganic insulating layer IOINS2 may contact the respective inner surfaces of the trenches TRCH of the first organic insulating layer OINS1. The second inorganic insulating layer IOINS2 may have a thickness that reduces a width of the trench TRCH.

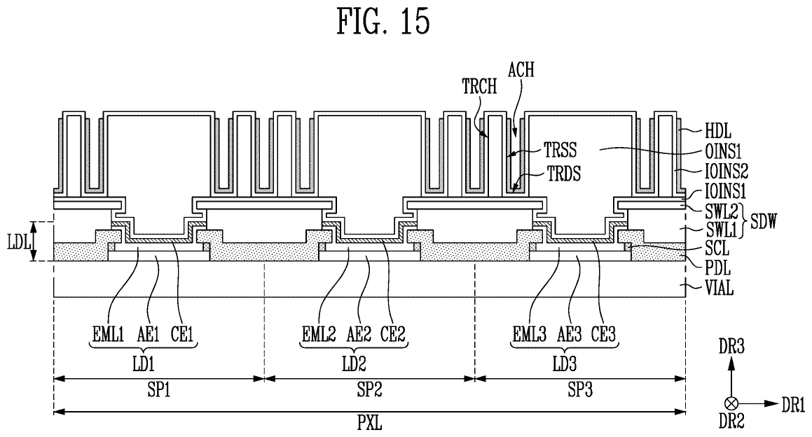

Referring to FIG. 15, the hydrophobic layers HDL may be formed on the second inorganic insulating layer IOINS2. The hydrophobic layers HDL may be formed to define a width of the air cavities ACH in the trenches TRCH. For example, the hydrophobic layers HDL may have a thickness that further reduces the width of the trench TRCH. During a process of forming the second organic insulating layer OINS2 (refer to FIG. 6) covering the second inorganic insulating layer IOINS2, the hydrophobic layers HDL may inhibit or prevent intrusion of the second organic insulating layer OINS2 into the trenches TRCH and may define the air cavities ACH in the trenches TRCH.

For example, the hydrophobic layers HDL may cover at least a portion of the second inorganic insulating layer IOINS2 in the trenches TRCH. The hydrophobic layers HDL may be formed to contact the inner surfaces of the second inorganic insulating layer IOINS2 disposed in the trenches TRCH. In other words, the hydrophobic layers HDL may contact side surfaces TRSS of the second inorganic insulating layer IOINS disposed in the trenches TRCH, and lower surfaces TRDS adjacent to the sidewall structures SDW.

The hydrophobic layers HDL may be disposed between the second inorganic insulating layer IOINS2 and the air cavities ACH. The hydrophobic layers HDL may inhibit or prevent the second organic insulating layer OINS2 from being deposited in the air cavities ACH.

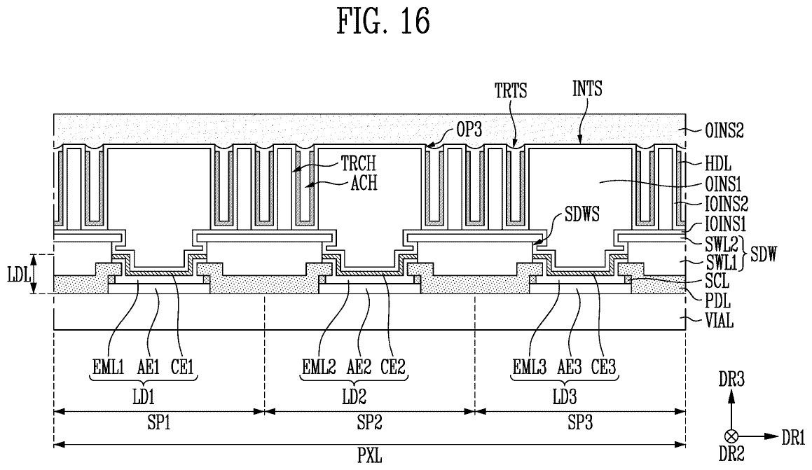

Referring to FIG. 16, the second organic insulating layer OINS2 may be formed on the second inorganic insulating layer IOINS2. The second organic insulating layer OINS2 may be formed to cover a surface INTS of the second inorganic insulating layer IOINS2. The second organic insulating layer OINS2 may cap the trenches TRCH. For example, the second organic insulating layer OINS2 may contact the air cavities ACH on an upper surface TRTS of each of the trenches TRCH. The second organic insulating layer OINS2 may contact a surface INTS of the second inorganic insulating layer IOINS2 except for the trenches TRCH. For example, the plurality of air cavities ACH may be defined by the trenches TRCH and the second organic insulating layer OINS2.

The second organic insulating layer OINS2 may be formed by a vapor deposition method, a printing method, or a slit coating method. The second organic insulating layer OINS2 may cover openings OP3 of the trenches TRCH due to low surface energy in the trenches TRCH. The second organic insulating layer OINS2 may cover openings OP3 of the trenches TRCH capping the trenches TRCH. As the second organic insulating layer OINS2 is coated, an edge portion of each of the openings OP3 may be more reliably formed in a semi-circular shape due to surface energy. For example, the edge portion of the second organic insulating layer OINS2 may protrude into each of the openings OP3, and may form a semi-circular shape extending toward the substrate SUB.

As such, since the air cavities ACH are disposed between the second inorganic insulating layer IOINS2 and the second organic insulating layer OINS2 in the trenches TRCH, the permittivity between the cathode electrodes CE1 to CE3 under the first organic insulating layer OINS1 and the touch electrodes over the second organic insulating layer OINS2 may be reduced. For example, the first organic insulating layer OINS1 including the air cavities ACH may have a permittivity of about 2.5 or less.

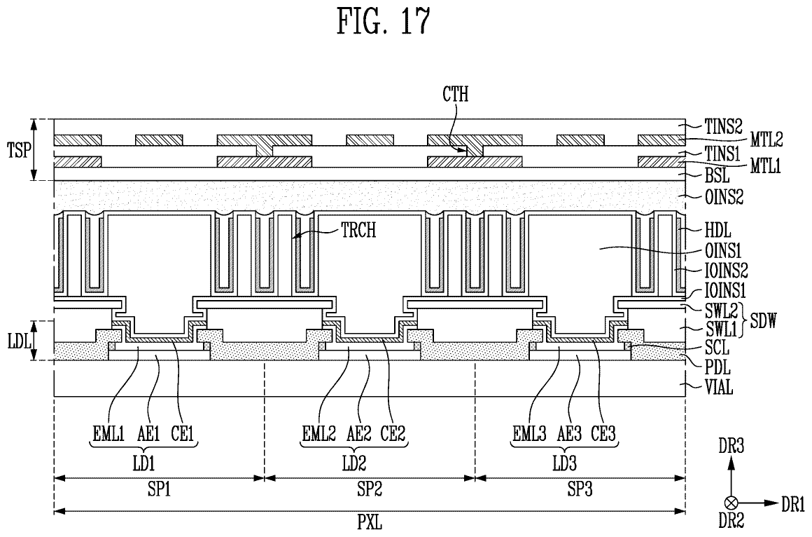

Referring to FIG. 17, the sensing panel TSP (or the touch sensor) may be formed on the second organic insulating layer OINS2. The touch base layer BSL may be formed on the second organic insulating layer OINS2. The first and second conductive patterns MTL1 and MTL2 may be formed on the touch base layer BSL with the first touch insulating layer TINS1 interposed therebetween. The second touch insulating layer TINS2 may be formed on the second conductive patterns MTL2. Some of the second conductive patterns MTL2 may be electrically connected to the first conductive patterns MTL1 through contact holes CTH passing through the first touch insulating layer TINS1. The first and second conductive patterns MTL1 and MTL2 may be provided as touch electrodes.

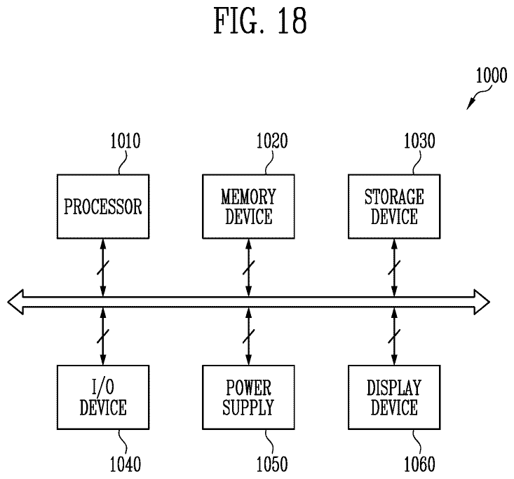

FIG. 18 is a schematic block diagram illustrating an electronic device 1000 including a display device in accordance with an embodiment.

Referring to FIGS. 18, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems.

The processor 1010 may perform specific calculations or tasks. In an embodiment, the processor 1010 may be a microprocessor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to control signals or data from the processor 1010. The display device 1060 may be connected to other components through the buses or other communication links.

In the display device in accordance with embodiments of the present disclosure, as the air cavities ACH are defined in the trenches TRCH of the first organic insulating layer OINS1, the permittivity between the touch electrodes TE and RE and the cathode electrodes CE1 to CE3 may be reduced. The structure including the air cavities ACH may have a reduced permittivity relative to a permittivity of a material forming the first organic insulating layer OINS1 without air cavities, which may reduce the capacitance between the touch electrodes TE and RE and the cathode electrodes CE1 to CE3. Further, the structure including the air cavities ACH may have decreased noise in signals generated by touch and improved touch sensitivity.

Various embodiments of the present disclosure may provide a display device having improved efficiency, and a method of fabricating the display device.

The effects of the present disclosure are not limited by the foregoing, and other various effects are anticipated herein.

Although embodiments and implementations have been described herein, other embodiments and modifications will be apparent from the foregoing description. Accordingly, the concepts of the present disclosure are not limited to embodiments described herein, but rather to the broader scope of the presented claims and various obvious modifications and equivalent arrangements.

What is claimed is:

1. A display device, comprising:
a substrate;
a pixel circuit layer disposed on the substrate;
a light-emitting-element layer disposed on the pixel circuit layer, and including light emitting elements;
a first inorganic insulating layer disposed on the light-emitting-element layer;
a first organic insulating layer disposed on the first inorganic insulating layer, and defining trenches in an area between the light emitting elements;
a second inorganic insulating layer disposed on the first organic insulating layer;
a second organic insulating layer disposed on the second inorganic insulating layer and capping the trenches;
a plurality of touch electrodes disposed on the second organic insulating layer; and
a plurality of air cavities defined by the trenches and the second organic insulating layer.

2. The display device according to claim 1, wherein the second inorganic insulating layer contacts inner surfaces of the trenches.

3. The display device according to claim 1, further comprising a hydrophobic layer disposed in the trenches and between the second inorganic insulating layer and the plurality of air cavities.

4. The display device according to claim 3, wherein the hydrophobic layer contacts the second inorganic insulating layer in the trenches.

5. The display device according to claim 4, wherein a contact angle of the hydrophobic layer with respect to the second organic insulating layer is 90 degrees or more.

6. The display device according to claim 1, wherein the plurality of air cavities are disposed between the plurality of touch electrodes and the light emitting elements.

7. The display device according to claim 1,
wherein the substrate includes a display area and a non-display area formed around the display area,
wherein the plurality of air cavities include first air cavities disposed adjacent to a center portion of the display area, and second air cavities disposed adjacent to the non-display area, and
wherein a number of first air cavities per unit surface area is equal to or greater than a number of second air cavities per unit surface area.

8. The display device according to claim 7, wherein any one of the second air cavities has a shape different from a shape of any one of the first air cavities.

9. The display device according to claim 1, wherein the light-emitting-element layer further includes:
anode electrodes disposed on the pixel circuit layer;
a sacrificial layer disposed on the anode electrodes along a peripheral portion of each of the anode electrodes; and
a pixel defining layer disposed on the pixel circuit layer, portions of the anode electrodes, and the sacrificial layer.

10. The display device according to claim 9, wherein the trenches overlap the pixel defining layer.

11. The display device according to claim 9, further comprising a sidewall structure disposed between the light-emitting-element layer and the first inorganic insulating layer, and overlapping the pixel defining layer.

12. The display device according to claim 11,
wherein the sidewall structure includes a first metal layer adjacent to the pixel defining layer, and a second metal layer disposed on the first metal layer, and
wherein the second metal layer has a width greater than a width of the first metal layer.

13. The display device according to claim 11, wherein the light-emitting-element layer further includes:
emission layers disposed on the anode electrodes; and
cathode electrodes disposed on the emission layers,
wherein the emission layers and the cathode electrodes contact side surfaces of the sidewall structure.

14. The display device according to claim 13, wherein the first inorganic insulating layer contacts the sidewall structure and the cathode electrodes.

15. The display device according to claim 1, wherein the first organic insulating layer has a permittivity of about 2.5 or less.

16. A method of fabricating a display device, comprising:
forming a pixel circuit layer on a substrate;
forming a light-emitting-element layer including light emitting elements on the pixel circuit layer;
forming a first inorganic insulating layer on the light-emitting-element layer;
forming, on the first inorganic insulating layer, a first organic insulating layer defining trenches in an area between the light emitting elements;
forming a second inorganic insulating layer on the first organic insulating layer;
forming a second organic insulating layer on the second inorganic insulating layer; and
providing a plurality of touch electrodes on the second organic insulating layer,
wherein air cavities are disposed in the trenches between the second inorganic insulating layer and the second organic insulating layer.

17. The method according to claim 16, further comprising forming, in the trenches, hydrophobic layers contacting the second inorganic insulating layer.

18. The method according to claim 16, further comprising providing a sensing panel including the plurality of touch electrodes on the second organic insulating layer.

19. An electronic device comprising:
a display panel; and
a sensing panel disposed on the display panel, and including touch electrodes,
wherein the display panel comprises:
a substrate;
a pixel circuit layer disposed on the substrate;
a light-emitting-element layer disposed on the pixel circuit layer, and including light emitting elements;
a first inorganic insulating layer disposed on the light-emitting-element layer;
a first organic insulating layer disposed on the first inorganic insulating layer, and defining trenches in an area between the light emitting elements;
a second inorganic insulating layer disposed on the first organic insulating layer;
a second organic insulating layer disposed on the second inorganic insulating layer; and
a plurality of air cavities disposed in the trenches between the second inorganic insulating layer and the second organic insulating layer.

20. The electronic device according to claim 19, further comprising a hydrophobic layer disposed in the trenches and between the second inorganic insulating layer and the plurality of air cavities,
wherein the hydrophobic layer contacts the second inorganic insulating layer in the trenches.
